(19) United States
(12) Patent Application Publication
(10) Pub. No.: US 2026/0371562 A1
(43) Pub. Date: Nov. 19, 2026

(54) INTEGRATED CIRCUIT DEVICE

(71) Applicant: Samsung Electronics Co., Ltd., Suwon-si (KR)

(72) Inventors: Cheolhyun An, Suwon-si (KR); Jiwoon Park, Suwon-si (KR); Hanjin Lim, Suwon-si (KR)

(73) Assignee: Samsung Electronics Co., Ltd., Suwon-si (KR)

(21) Appl. No.: 19/640,960

(22) Filed: Apr. 7, 2026

(30) Foreign Application Priority Data
May 15, 2025 (KR) 10-2025-0063521

(51) Int. Cl. H10B 12/00; H10D 1/68

(52) U.S. Cl. CPC H10B 12/318; H10B 12/315; H10D 1/696; H10B 12/0335

(57) ABSTRACT

An integrated circuit device includes a conductive region, and a capacitor on the conductive region, the capacitor including a lower electrode structure, an upper electrode, and a dielectric film, wherein the lower electrode structure includes an outer template electrode portion contacting the dielectric film and including a first metal oxide having a rutile-phase crystal structure, a main electrode portion contacting the outer template electrode portion, the main electrode portion including a second metal oxide and being spaced apart from the dielectric film with the outer template electrode portion therebetween, wherein the second metal oxide includes a different material from a material of the first metal oxide and has a rutile-phase crystal structure, and a bottom bridge electrode portion located between the conductive region and the outer template electrode portion, the bottom bridge electrode portion including a conductive metal nitride.

### CROSS-REFERENCE TO RELATED APPLICATIONS

This present application claims priority to and the benefit under 35 U.S.C. § 119(a)-(d) of Korean Patent Application No. 10-2025-0063521, filed on May 15, 2025, in the Korean Intellectual Property Office, the entire disclosure of which is incorporated herein by reference.

### FIELD

The disclosed concepts relate to an integrated circuit (IC) device, and more particularly, to an IC device including a capacitor.

### BACKGROUND

With the downscaling of IC devices, spaces occupied by capacitors are also rapidly shrinking. Thus, it is necessary to develop techniques capable of optimizing structures of capacitors so as to overcome spatial and design-rule limitations and provide relatively high capacitance.

### SUMMARY

The disclosed concepts provide an integrated circuit (IC) device including a capacitor having improved electrical properties and reliability.

According to aspects of the disclosed concepts, there is provided an IC device including a conductive region on a substrate, and a capacitor located on the conductive region, the capacitor including a lower electrode structure, an upper electrode, and a dielectric film located between the lower electrode structure and the upper electrode, wherein the lower electrode structure includes an outer template electrode portion spaced apart from the conductive region in a substantially vertical direction, the outer template electrode portion being in contact with the dielectric film and including a first metal oxide having a rutile-phase crystal structure, a main electrode portion having a first bottom surface and a first outer sidewall, wherein the first bottom surface and the first outer sidewall are in contact with the outer template electrode portion, the main electrode portion including a second metal oxide and being spaced apart from the dielectric film with the outer template electrode portion therebetween, wherein the second metal oxide includes a different material from a material of the first metal oxide and has a rutile-phase crystal structure, and a bottom bridge electrode portion located between the conductive region and the outer template electrode portion and spaced apart in the substantially vertical direction from the main electrode portion with the outer template electrode portion therebetween, the bottom bridge electrode portion including a conductive metal nitride.

According to aspects of the disclosed concepts, there is provided an IC device including a conductive region on a substrate, a lower electrode structure located on the conductive region, a support film configured to support the lower electrode structure around the lower electrode structure, an upper electrode facing the lower electrode structure on the substrate, and a dielectric film located between the lower electrode structure and the upper electrode, wherein the lower electrode structure includes an outer template electrode portion spaced apart from the conductive region in a substantially vertical direction, the outer template electrode portion being in contact with the dielectric film and including a first metal oxide having a rutile-phase crystal structure, a main electrode portion having a first bottom surface and a first outer sidewall in contact with the outer template electrode portion, the main electrode portion including a second metal oxide and being spaced apart from the dielectric film with the outer template electrode portion therebetween, wherein the second metal oxide includes a different material from a material of the first metal oxide and has a rutile-phase crystal structure, a bottom bridge electrode portion located between the conductive region and the outer template electrode portion and spaced apart in the substantially vertical direction from the main electrode portion with the outer template electrode portion therebetween, and a side bridge electrode portion located between the outer template electrode portion and the support film and spaced apart from the bottom bridge electrode portion, wherein the bottom bridge electrode portion and the side bridge electrode portion include the same conductive metal nitride.

According to aspects of the disclosed concepts, there is provided an IC device including a conductive region on a substrate, a lower electrode structure located on the conductive region, a support film configured to support the lower electrode structure around the lower electrode structure, an upper electrode facing the lower electrode structure on the substrate, and a dielectric film located between the lower electrode structure and the upper electrode, wherein the lower electrode structure includes an outer template electrode portion spaced apart from the conductive region in a substantially vertical direction, the outer template electrode portion being in contact with the dielectric film and including tin oxide having a rutile-phase crystal structure, a main electrode portion having a first bottom surface and a first outer sidewall, wherein the first bottom surface and the first outer sidewall are in contact with the outer template electrode portion, the main electrode portion including vanadium oxide, molybdenum oxide, niobium oxide, cobalt oxide, or a combination thereof and having a rutile-phase crystal structure, and the main electrode portion being spaced apart from the dielectric film with the outer template electrode portion therebetween, a bottom bridge electrode portion located between the conductive region and the outer template electrode portion and spaced apart in the substantially vertical direction from the main electrode portion with the outer template electrode portion therebetween, and a side bridge electrode portion located between the outer template electrode portion and the support film and spaced apart from the bottom bridge electrode portion, wherein each of the bottom bridge electrode portion and the side bridge electrode portion includes titanium nitride (TiN), and the dielectric film includes a TiO₂ film having a rutile-phase crystal structure, the TiO₂ film being in contact with the outer template electrode portion.

According to aspects of the disclosed concepts, there is provided a method of manufacturing an IC device. The method includes forming a mold structure on a conductive region formed on a substrate. A vertical hole exposing the conductive region is formed in the mold structure. A preliminary bridge electrode layer is formed to cover the conductive region and the mold structure inside the vertical hole. An outer template electrode portion and a main electrode portion are formed. The outer template electrode portion is formed on the preliminary bridge electrode layer inside the vertical hole and includes a first metal oxide having a rutile-phase crystal structure. The main electrode portion covers the outer template electrode portion inside the vertical hole and includes a second metal oxide. The second metal oxide includes a different material from a material of the first metal oxide and has a rutile-phase crystal structure. A portion of the mold structure is removed to expose a sidewall of the preliminary bridge electrode layer. A portion of the preliminary bridge electrode layer is removed from the exposed sidewall of the preliminary bridge electrode layer to expose an outer sidewall of the outer template electrode portion. A dielectric film is formed to be in contact with the outer sidewall of the outer template electrode portion.

In embodiments, the removal of the portion of the preliminary bridge electrode layer may include forming a bottom bridge electrode portion, which includes the remaining portion of the preliminary bridge electrode layer. The bottom bridge electrode portion may be formed to be located between the conductive region and the outer template electrode portion.

In embodiments, the removal of the portion of the preliminary bridge electrode layer may include forming a side bridge electrode portion, which includes the remaining other portion of the preliminary bridge electrode layer.

In embodiments, the side bridge electrode portion may be formed to protrude from the outer sidewall of the outer template electrode portion in a substantially lateral direction substantially parallel to a main surface of the substrate.

In embodiments, the formation of the dielectric film may include forming a TiO₂ film having a rutile-phase crystal structure to be in contact with the outer sidewall of the outer template electrode portion.

In embodiments, the formation of the mold structure may include sequentially forming a first mold film, a first support film, a second mold film, and a second support film on the substrate. Each of the first support film and the second support film may include a material having an etch selectivity with respect to the first mold film and the second mold film, and the removal of the portion of the mold structure may include selectively removing the first mold film and the second mold film, from among the first mold film, the first support film, the second mold film, and the second support film.

In embodiments, the preliminary bridge electrode layer may include a conductive metal nitride.

In embodiments, after the formation of the outer template electrode portion and the main electrode portion and before the removal of the portion of the mold structure, the method may further include forming a capping electrode portion covering an uppermost surface of each of the outer template electrode portion and the main electrode portion. The capping electrode portion may include a conductive metal nitride.

In embodiments, the outer template electrode portion may include a dopant-free tin oxide or tin oxide including a dopant containing at least one element selected from niobium (Nb), antimony (Sb), and tantalum (Ta).

In embodiments, the main electrode portion may include vanadium oxide, molybdenum oxide, niobium oxide, cobalt oxide, or a combination thereof, and the main electrode portion may include a Sn dopant at a content selected in a range of about 0 atomic percent (at %) to about 10 at %.

In embodiments, the main electrode portion may have a pillar shape with a filled interior or a cup-shaped cross-sectional structure.

### BRIEF DESCRIPTION OF THE DRAWINGS

Embodiments will be more clearly understood from the following detailed description taken in conjunction with the accompanying drawings in which:

FIG. 1 is a schematic plan layout illustrating some components of a memory cell array region of an integrated circuit (IC) device according to embodiments;

FIG. 2 is a cross-sectional view of some components of an IC device according to embodiments;

FIG. 3 is a plan view showing examples of planar shapes of a plurality of lower electrode structures and a second support film in an IC device according to embodiments;

FIG. 4 is a cross-sectional view of some components of an IC device according to embodiments;

FIG. 5 is a cross-sectional view of some components of an IC device according to still embodiments;

FIGS. 6A to 6K are cross-sectional views of a process sequence of a method of manufacturing an IC device, according to embodiments; and

FIGS. 7A to 7E are cross-sectional views of a process sequence of a method of manufacturing an IC device, according to embodiments.

### DETAILED DESCRIPTION

Hereinafter, embodiments will be described in detail with reference to the accompanying drawings. The same reference numerals are used to denote the same elements in the drawings, and repeated descriptions thereof will be omitted.

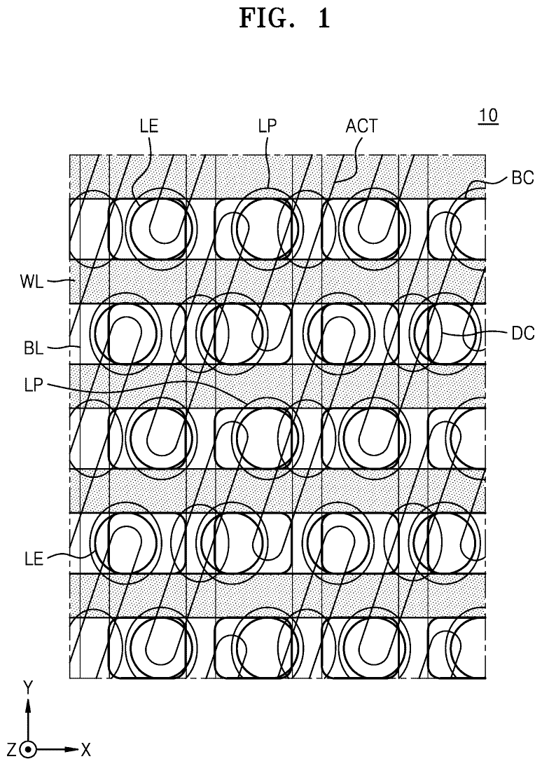

FIG. 1 is a schematic plan layout illustrating some components of a memory cell array region of an integrated circuit (IC) device 10 according to embodiments. The IC device 10 may constitute a dynamic random access memory (DRAM) device.

Referring to FIG. 1, the IC device 10 may include a plurality of active regions ACT, which are arranged to laterally extend in an oblique direction to each of a first lateral direction (X direction) and a second lateral direction (Y direction) orthogonal to the first lateral direction (X direction), in a view from above. A plurality of word lines WL may intersect with the plurality of active regions ACT and extend parallel to each other in the first lateral direction (X direction). On the plurality of word lines WL, a plurality of bit lines BL may extend parallel to each other in the second lateral direction (Y direction). Each of the plurality of bit lines BL may be connected to the active region ACT through a direct contact DC.

A plurality of buried contacts BC may be formed between two adjacent ones of the plurality of bit lines BL. A plurality of conductive landing pads LP may be formed on the plurality of buried contacts BC. Each of the plurality of conductive landing pads LP may be arranged to overlap at least a portion of the buried contact BC. A plurality of lower electrode structures LE may be formed on the plurality of conductive landing pads LP. The plurality of lower electrode structures LE may be connected to the plurality of active regions ACT through the plurality of buried contacts BC and the plurality of conductive landing pads LP.

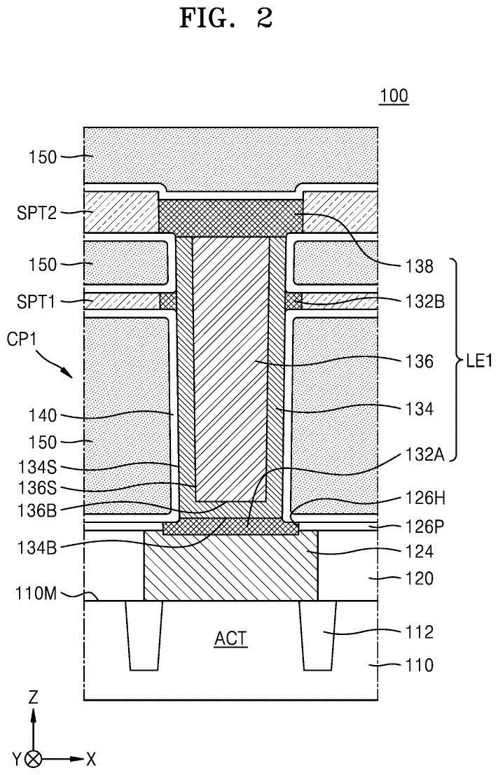

FIG. 2 is a cross-sectional view of some components of an IC device 100 according to embodiments.

Referring to FIG. 2, the IC device 100 may constitute a portion of the IC device 10 shown in FIG. 1. Some components of the IC device 100 are omitted or illustrated in a simplified manner in FIG. 2. However, it should be understood that a configuration of the IC device 100 is not limited to that shown in FIG. 2, but includes characteristic configurations described below.

The IC device 100 may include a substrate 110 including a plurality of active regions ACT and a lower structure 120 formed on the substrate 110. A conductive region 124 may pass through the lower structure 120 and be connected to the active region ACT.

The substrate 110 may include a semiconductor element, such as silicon (Si) and germanium (Ge), or a compound semiconductor, such as silicon carbide (SiC), gallium arsenide (GaAs), indium arsenide (InAs), and indium phosphide (InP). The substrate 110 may include a semiconductor substrate and structures including at least one insulating film or at least one conductive region, which are formed on the semiconductor substrate. The conductive region may include, for example, a doped well or a doped structure. In embodiments, the substrate 110 may have various device isolation structures, such as a shallow trench isolation (STI) structure. The plurality of active regions ACT may be defined by a plurality of device isolation regions 112 in the substrate 110. The device isolation region 112 may include an oxide film, a nitride film, or a combination thereof.

In embodiments, the lower structure 120 may include an insulating film, which includes a silicon oxide film, a silicon nitride film, or a combination thereof. In embodiments, the lower structure 120 may include various conductive regions, for example, wiring layers, contact plugs, transistors, and insulating films configured to insulate the wiring layers, the contact plugs, and transistors from each other. The conductive region 124 may include polysilicon, a metal, a conductive metal nitride, a metal silicide, or a combination thereof. The lower structure 120 may include the plurality of bit lines BL described with reference to FIG. 1. The conductive region 124 may include a buried contact BC and a conductive landing pad LP, which have been described with reference to FIG. 1.

An insulating pattern 126P having an opening 126H may be located on the lower structure 120 and the conductive region 124. The insulating pattern 126P may include silicon nitride, silicon oxynitride, or a combination thereof.

A lower electrode structure LE1 may be arranged on the conductive region 124. The lower electrode structure LE1 may constitute the lower electrode structure LE described with reference to FIG. 1. The lower electrode structure LE1 may extend lengthwise from a top surface of the conductive region 124 in a vertical direction (Z direction) through the opening 126H of the insulating pattern 126P. A dielectric film 140 and an upper electrode 150 may be formed on the lower electrode structure LE1. The dielectric film 140 may be located between the lower electrode structure LE1 and the upper electrode 150. The lower electrode structure LE1, the dielectric film 140, and the upper electrode 150 may constitute a capacitor CP1.

The lower electrode structure LE1 may include a bottom bridge electrode portion 132A, an outer template electrode portion 134, and a main electrode portion 136, which are sequentially formed on the conductive region 124.

The bottom bridge electrode portion 132A may be located between the conductive region 124 and the outer template electrode portion 134. The conductive region 124 may be spaced apart in the vertical direction (Z direction) from the outer template electrode portion 134 with the bottom bridge electrode portion 132A therebetween. The bottom bridge electrode portion 132A may have a bottom surface in contact with the conductive region 124 and a top surface in contact with the outer template electrode portion 134. The bottom bridge electrode portion 132A may be spaced apart in the vertical direction (Z direction) from the main electrode portion 136 with the outer template electrode portion 134 therebetween. The bottom bridge electrode portion 132A may include a portion in contact with the dielectric film 140. The bottom bridge electrode portion 132A may be spaced apart from the upper electrode 150 with the dielectric film 140 therebetween.

In embodiments, the bottom bridge electrode portion 132A may include a conductive metal nitride. For example, the bottom bridge electrode portion 132A may include titanium nitride (TiN). In embodiments, the bottom bridge electrode portion 132A may have a thickness selected in a range of about 1 Å to about 50 Å in the vertical direction (Z direction). The vertical direction (Z direction) may be a direction perpendicular to a main surface 110M of the substrate 110.

The outer template electrode portion 134 may be spaced apart from the conductive region 124 in the vertical direction (Z direction) and may include a first metal oxide having a rutile-phase crystal structure. A bottom surface 134B of the outer template electrode portion 134 may face the conductive region 124 and contact the bottom bridge electrode portion 132A. An outer sidewall 134S of the outer template electrode portion 134 may face the upper electrode 150 and contact the dielectric film 140.

In embodiments, the outer template electrode portion 134 may include dopant-free tin oxide. The tin oxide may include SnOₓ (1.5≤x≤2.0). For example, the tin oxide may include SnO₂. In embodiments, the outer template electrode portion 134 may include dopant-containing tin oxide. The dopant included in the outer template electrode portion 134 may be selected from niobium (Nb), antimony (Sb), and tantalum (Ta). For example, the outer template electrode portion 134 may include a SnO₂ film including a dopant selected from Nb, Sb, and Ta. A content of the dopant in the outer template electrode portion 134 may be selected in a range of about 0 at % to about 10 at %. In the outer template electrode portion 134, the dopant may improve the chemical stability of O₂ at room temperature (e.g., a temperature of about 20 °C to about 28 °C), thereby lowering the possibility of reduction of a Sn element included in the outer template electrode portion 134 and preventing or minimizing a reduction in the electrical conductivity of the outer template electrode portion 134. In embodiments, the outer template electrode portion 134 may have a thickness selected in a range of about 1 Å to about 50 Å in the vertical direction (Z direction).

The main electrode portion 136 may be spaced apart in the vertical direction (Z direction) from the conductive region 124 with the bottom bridge electrode portion 132A and the outer template electrode portion 134 therebetween. The main electrode portion 136 may include a second metal oxide, which includes a different material from the first metal oxide included in the outer template electrode portion 134 and has a rutile-phase crystal structure. The main electrode portion 136 may have a bottom surface 136B and an outer sidewall 136S, which are in contact with the outer template electrode portion 134. The bottom surface 136B of the main electrode portion 136 may face the conductive region 124 and contact the outer template electrode portion 134. The outer sidewall 136S of the main electrode portion 136 may face the upper electrode 150 and the dielectric film 140 and contact the outer template electrode portion 134. The outer sidewall 136S of the main electrode portion 136 may be spaced apart from the dielectric film 140 with the outer template electrode portion 134 therebetween. As used herein, the bottom surface 136B of the main electrode portion 136 may be referred to as a first bottom surface, and a bottom surface 134B of the outer template electrode portion 134 may be referred to as a second bottom surface. As used herein, the outer sidewall 136S of the main electrode portion 136 may be referred to as a first outer sidewall, and the outer sidewall 134S of the outer template electrode portion 134 may be referred to as a second outer sidewall.

In embodiments, the second metal oxide included in the main electrode portion 136 may include vanadium oxide, molybdenum oxide, niobium oxide, cobalt oxide, or a combination thereof. The vanadium oxide may include VOₓ (1.5≤x≤3.0). For example, the vanadium oxide may include VO₂, V₂O₅, or VO₃. The molybdenum oxide may include MoOₓ (1.5≤x≤3.0). For example, the molybdenum oxide may include MoO₂ or MoO₃. The niobium oxide may include NbOₓ (1.5≤x≤3.0). For example, the niobium oxide may include NbO, NbO₂, or Nb₂O₅. The cobalt oxide may include CoOₓ (1.5≤x≤2.0). For example, the cobalt oxide may include CoO, Co₂O₃, or Co₃O₄.

In embodiments, the second metal oxide included in the main electrode portion 136 may not include a dopant. In embodiments, the second metal oxide included in the main electrode portion 136 may include a dopant including Sn. A content of the dopant in the main electrode portion 136 may be selected in a range of about 0 at % to about 10 at %. Because the second metal oxide included in the main electrode portion 136 has relatively high electrical conductivity and thermal stability, leakage current may be inhibited from being generated in the capacitor CP1, and the capacitor CP1 may provide relatively high capacitance.

The main electrode portion 136 may have a pillar shape with a filled interior. Accordingly, any other constituent materials, except for materials (e.g., the second metal oxide) included in the main electrode portion 136 and the dopant that may be included as needed, may not be present inside the main electrode portion 136 defined by the outer sidewall 136S of the main electrode portion 136.

The lower electrode structure LE1 of the capacitor CP1 may further include a capping electrode portion 138 covering an uppermost surface of each of the outer template electrode portion 134 and the main electrode portion 136. In embodiments, the capping electrode portion 138 may include a conductive metal nitride. For example, the capping electrode portion 138 may include TiN. In embodiments, a constituent material of the capping electrode portion 138 may be the same as that of the bottom bridge electrode portion 132A. In a lateral direction parallel to the main surface 110M of the substrate 110, a width of the capping electrode portion 138 may be greater than a maximum width of each of the outer template electrode portion 134 and the main electrode portion 136.

The lower electrode structure LE1 of the capacitor CP1 may further include at least one side bridge electrode portion 132B, which protrudes from the outer sidewall 134S of the outer template electrode portion 134 at a third vertical level. The third vertical level may be between a first vertical level of the bottom bridge electrode portion 132A and a second vertical level of the capping electrode portion 138. The at least one side bridge electrode portion 132B may protrude toward the outside of the lower electrode structure LE1 in a lateral direction parallel to the main surface 110M of the substrate 110. As used herein, a vertical level refers to a distance from the main surface 110M of the substrate 110 in the vertical direction (Z direction). In the lower electrode structure LE1, the side bridge electrode portion 132B may be arranged apart from each of the capping electrode portion 138 and the bottom bridge electrode portion 132A.

In embodiments, the side bridge electrode portion 132B may include a conductive metal nitride. For instance, the side bridge electrode portion 132B may include TiN. In embodiments, a constituent material of the side bridge electrode portion 132B may be the same as that of the bottom bridge electrode portion 132A. In embodiments, the bottom bridge electrode portion 132A, the side bridge electrode portion 132B, and the capping electrode portion 138 may include the same conductive metal nitride. In the lower electrode structure LE1, each of the bottom bridge electrode portion 132A, the side bridge electrode portion 132B, and the capping electrode portion 138 may have a surface in contact with the dielectric film 140.

At least one support film configured to support the lower electrode structure LE1 may be arranged around the lower electrode structure LE1. The at least one support film may include a first support film SPT1 and a second support film SPT2, which are spaced apart from each other in the vertical direction (Z direction). The lower electrode structure LE1 may constitute the lower electrode structure LE described with reference to FIG. 1.

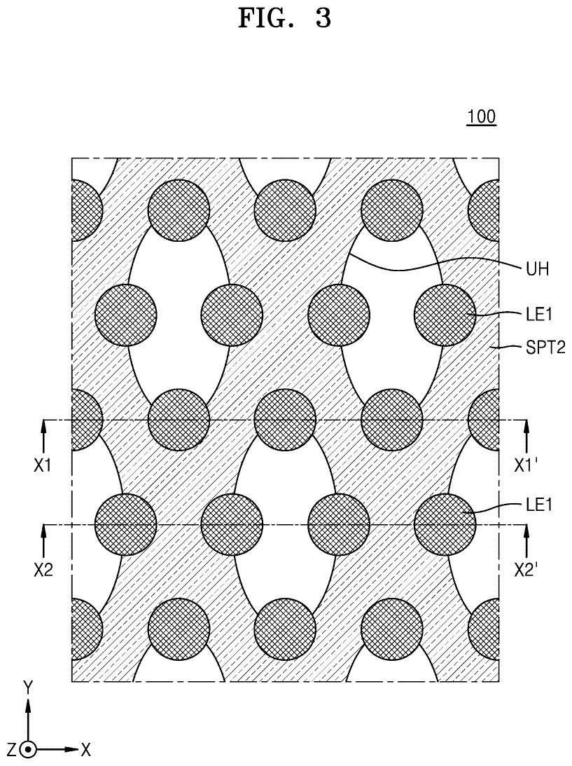

FIG. 3 is a plan view showing examples of planar shapes of a plurality of lower electrode structures LE1 and a second support film SPT2 configured to support the plurality of lower electrode structures LE1 in the IC device 100. A cross-sectional configuration shown in FIG. 2 may correspond to a partial region of a cross-section taken along line X1-X1′ of FIG. 3.

Referring to FIGS. 2 and 3, the plurality of lower electrode structures LE1 may be supported by the first support film SPT1 and the second support film SPT2. The second support film SPT2 may be arranged apart in a vertical direction (Z direction) from the substrate 110 with the first support film SPT1 therebetween.

The plurality of lower electrode structures LE1 may be opposite to the upper electrode 150 with a dielectric film 140 therebetween. The dielectric film 140 may cover the lower electrode structure LE1, the first support film SPT1, and the second support film SPT2. The dielectric film 140 may include portions respectively in contact with the insulating pattern 126P, the first support film SPT1, the second support film SPT2, and an outer template electrode portion 134 of the lower electrode structure LE1.

The second support film SPT2 may extend in a lateral direction parallel to a main surface 110M of the substrate 110 while surrounding an upper end of each of the plurality of lower electrode structures LE1. The second support film SPT2 may include a plurality of upper holes UH passing through the plurality of lower electrode structures LE1. An inner sidewall of each of the plurality of upper holes UH included in the second support film SPT2 may be in contact with an outer sidewall of the lower electrode structure LE1. For example, the inner sidewall of each of the plurality of upper holes UH included in the second support film SPT2 may be in contact with an outer sidewall of a capping electrode portion 138 included in the lower electrode structure LE1. In the plurality of lower electrode structures LE1, a vertical level of an uppermost surface of the capping electrode portion 138 may be closer to the substate 110 than a vertical level of an uppermost surface of the second support film SPT2. A vertical distance from the main surface 110M of the substrate 110 to the uppermost surface of the second support film SPT2 may be greater than a vertical distance from the main surface 110M of the substrate 110 to the uppermost surface of the capping electrode portion 138 of each of the plurality of lower electrode structures LE1.

The first support film SPT1 may extend in a lateral direction parallel to the main surface 110M of the substrate 110 between the substrate 110 and the second support film SPT2 and be in contact with the outer sidewall of each of the plurality of lower electrode structures LE1. Similarly to the plurality of upper holes UH included in the second support film SPT2, the first support film SPT1 may include a plurality of lower holes passing through the plurality of lower electrode structures LE1. The plurality of lower electrode structures LE1 may pass through the plurality of upper holes UH formed in the second support film SPT2 and the plurality of lower holes formed in the first support film SPT1 and extend in the vertical direction (Z direction).

FIG. 3 illustrates an example of a planar structure in which four lower electrode structures LE1 are located adjacent to each other along the inner sidewall of each of the plurality of upper holes UH included in the second support film SPT2. However, a planar shape of each of the plurality of upper holes UH is not limited to that shown in FIG. 3 and may be variously changed and modified within the scope of the inventive concept. Each of the plurality of lower holes included in the first support film SPT1 may have a planar shape corresponding to the planar shape of each of the plurality of upper holes UH.

Each of the first support film SPT1 and the second support film SPT2 may include a silicon nitride film (SiN), a silicon carbonitride film (SiCN), a silicon boron nitride film (SiBN), or a combination thereof. In embodiments, the first support film SPT1 and the second support film SPT2 may include the same material. In embodiments, the first support film SPT1 and the second support film SPT2 may include different materials from each other. In an example, each of the first support film SPT1 and the second support film SPT2 may include SiCN. In another example, the first support film SPT1 may include SiCN, and the second support film SPT2 may include SiBN. However, the inventive concept is not limited to the materials described above.

Respective thicknesses of the first support film SPT1 and the second support film SPT2 in the vertical direction (Z direction) may be different from each other as shown in FIG. 2. For example, in the vertical direction (Z direction), the thickness of the second support film SPT2 may be greater than the thickness of the first support film SPT1. However, the inventive concept is not limited thereto, and the thickness of each of the first support film SPT1 and the second support film SPT2 in the vertical direction (Z direction) may be variously determined as needed. FIG. 2 illustrates a structure in which two support films including the first support film SPT1 and the second support film SPT2 are arranged around the lower electrode structure LE1, but the inventive concept is not limited thereto. For example, the IC device 100 may include one support film or at least three support films sequentially formed in the vertical direction (Z direction).

As shown in FIG. 2, a side bridge electrode portion 132B of the lower electrode structure LE1 may extend in a lateral direction toward the first support film SPT1 from an outer sidewall 134S of the outer template electrode portion 134. A width of the side bridge electrode portion 132B in a lateral direction may be defined by the outer sidewall 134S of the outer template electrode portion 134 and the first support film SPT1.

In the vertical direction (Z direction), a thickness of the capping electrode portion 138 may be greater than a thickness of the side bridge electrode portion 132B. A sidewall of the capping electrode portion 138, which is in contact with the second support film SPT2, may protrude in the lateral direction further outwardly from the lower electrode structure LE1 than the outer sidewall 134S of the outer template electrode portion 134. Each of the first support film SPT1 and the second support film SPT2 may support the lower electrode structure LE1 at a position apart from the outer template electrode portion 134.

The dielectric film 140 may conformally cover the outer sidewall of the lower electrode structure LE1, a bottom surface and a top surface of each of the first support film SPT1 and the second support film SPT2, and a top surface of the insulating pattern 126P. The dielectric film 140 may include a portion in contact with a portion, which is in a region between the insulating pattern 126P and the outer template electrode portion 134, of the bottom bridge electrode portion 132A of the lower electrode structure LE1. The dielectric film 140 may include a portion in contact with the uppermost surface of the capping electrode portion 138 of the lower electrode structure LE1. The dielectric film 140 may be in contact with a bottom surface and a top surface of the side bridge electrode portion 132B of the lower electrode structure LE1. The bottom surface of the side bridge electrode portion 132B may be a surface facing the substrate 110, and a top surface of the side bridge electrode portion 132B may be a surface opposite to the bottom surface of the side bridge electrode portion 132B. The dielectric film 140 may not include a portion in contact with a main electrode portion 136.

The dielectric film 140 may include a TiO₂ film having a rutile-phase crystal structure. At least a portion of the dielectric film 140, which is in contact with the outer template electrode portion 134 of the lower electrode structure LE1, may include a TiO₂ film having a rutile-phase crystal structure. In the lower electrode structure LE1, the outer template electrode portion 134 may act as a crystallization-inducing layer configured to induce the dielectric film 140 to have a rutile-phase crystal structure. For example, when the outer template electrode portion 134 includes a SnO₂ film having a rutile-phase crystal structure, a metal oxide included in the dielectric film 140 may maintain a rutile-phase crystal structure during the formation of the dielectric film 140 from a surface of the outer template electrode portion 134. Thus, the dielectric film 140 may provide a relatively high dielectric constant, and leakage current between the lower electrode structure LE1 and the dielectric film 140 may be reduced or eliminated.

In embodiments, the TiO₂ film having the rutile-phase crystal structure, which is included in the dielectric film 140, may further include a dopant. The dopant that may be included in the TiO₂ film may be selected from aluminum (Al), germanium (Ge), yttrium (Y), gallium (Ga), lanthanum (La), boron (B), indium (In), and scandium (Sc), without being limited thereto. In the TiO₂ film included in the dielectric film 140, a content of the dopant may be selected in a range of about 0 at % to about 10 at %.

In embodiments, the dielectric film 140 may have a single film structure including a TiO₂ film having a rutile-phase crystal structure. In this case, the dielectric film 140 may include an undoped rutile-phase TiO₂ film or a rutile-phase TiO₂ film doped with the dopant.

In embodiments, the dielectric film 140 may have a multilayered film structure including a TiO₂ film having a rutile-phase crystal structure and at least one high-k dielectric film. In this case, the TiO₂ film having the rutile-phase crystal structure may be in contact with the outer template electrode portion 134 of the lower electrode structure LE1, and the at least one high-k dielectric film may be spaced apart from the lower electrode structure LE1 with the TiO₂ film having the rutile-phase crystal structure therebetween. In embodiments, the at least one high-k dielectric film may include at least one metal selected from zirconium (Zr), titanium (Ti), strontium (Sr), hafnium (Hf), aluminum (Al), niobium (Nb), cerium (Ce), lanthanum (La), and tantalum (Ta). In embodiments, the at least one high-k dielectric film may include at least one selected from a ZrO₂ film, a TiO₂ film, a HfO₂ film, an Al₂O₃ film, a Nb₂O₅ film, a CeO₂ film, a La₂O₃ film, a Ta₂O₃ film, and a SrTiO₃ film. For instance, the at least one high-k dielectric film may include ZrO₂, SrTiO₃, or a combination thereof, without being limited thereto. In embodiments, the dielectric film 140 may have a thickness of about 10 Å to about 80 Å, without being limited thereto.

The upper electrode 150 may include a portion facing the lower electrode structure LE1 with the dielectric film 140 therebetween and portions facing the first support film SPT1 and the second support film SPT2 with the dielectric film 140 therebetween.

The upper electrode 150 may include a metal film, a conductive metal oxide film, a conductive metal nitride film, a conductive metal oxynitride film, or a combination thereof. In embodiments, the upper electrode 150 may include Nb, Nb oxide, Nb nitride, Nb oxynitride, Ti, Ti oxide, Ti nitride, Ti oxynitride, Co, Co oxide, Co nitride, Co oxynitride, Sn, Sn oxide, Sn nitride, Sn oxynitride, or a combination thereof. For example, the upper electrode 150 may include NbN, TiN, CON, SnO₂, or a combination thereof. In embodiments, the upper electrode 150 may include tantalum nitride (TaN), titanium aluminum nitride (TiAlN), tantalum aluminum nitride (TaAlN), vanadium (V), vanadium nitride (VN), molybdenum (Mo), molybdenum nitride (MoN), tungsten (W), tungsten nitride (WN), ruthenium (Ru), ruthenium oxide (RuO₂), strontium ruthenium oxide (SrRuO₃), iridium (Ir), iridium oxide (IrO₂), platinum (Pt), platinum oxide (PtO), SrRuO₃ (SRO), (Ba,Sr)RuO₃ (BSRO), CaRuO₃ (CRO), (La,Sr)CoO₃) (LSCo), or a combination thereof. However, a constituent material of the upper electrode 150 is not limited to the examples described above.

In the IC device 100 described with reference to FIGS. 2 and 3, the lower electrode structure LE1 of the capacitor CP1 may include the outer template electrode portion 134 and the main electrode portion 136. The outer template electrode portion 134 may be in contact with the dielectric film 140, and the main electrode portion 136 may be spaced apart from the dielectric film 140 and surrounded by the outer template electrode portion 134. Each of the outer template electrode portion 134 and the main electrode portion 136 may include a metal oxide having a rutile-phase crystal structure. When the dielectric film 140 is formed, the outer template electrode portion 134 may act as a crystallization-inducing layer configured to induce the dielectric film 140 to have a rutile-phase crystal structure. Due to the outer template electrode portion 134, a material included in the dielectric film 140 may easily maintain the rutile-phase crystal structure. Thus, the dielectric film 140 may provide a relatively high dielectric constant, leakage current between the lower electrode structure LE1 and the dielectric film 140 may be reduced or eliminated, and capacitance of the capacitor CP1 may increase. Accordingly, reliability of the IC device 100 may improve.

According to the IC device 100 described with reference to FIGS. 2 and 3, in the lower electrode structure LE1 of the capacitor CP1, a first metal oxide included in the outer template electrode portion 134 may include a different material from a second metal oxide included in the main electrode portion 136.

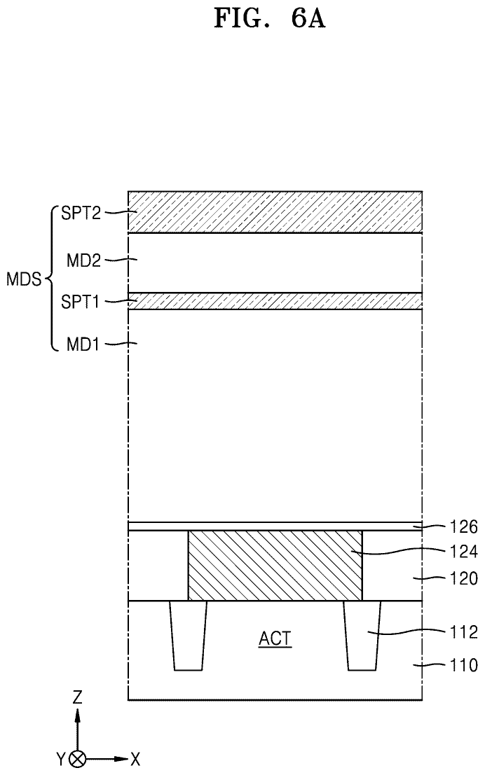

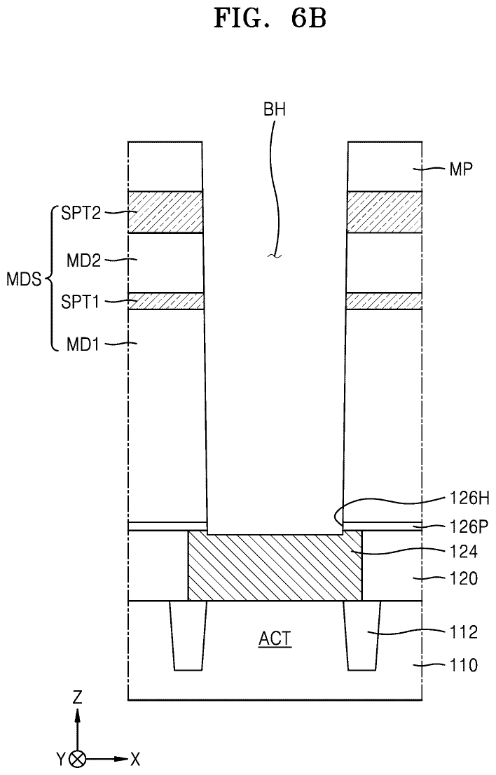

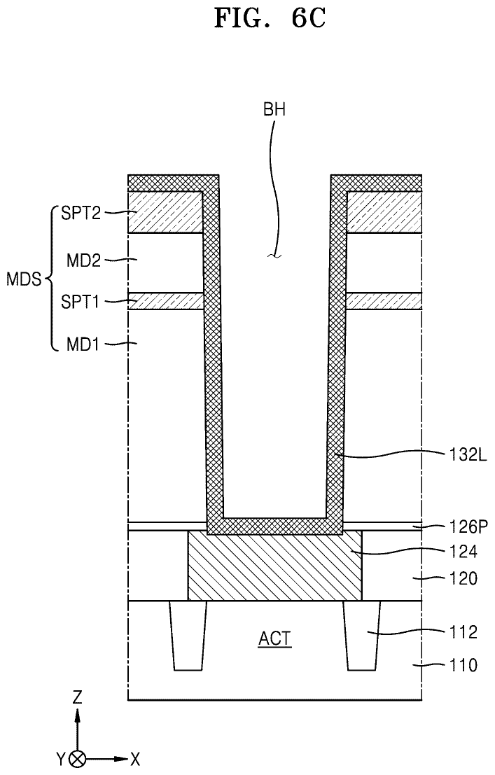

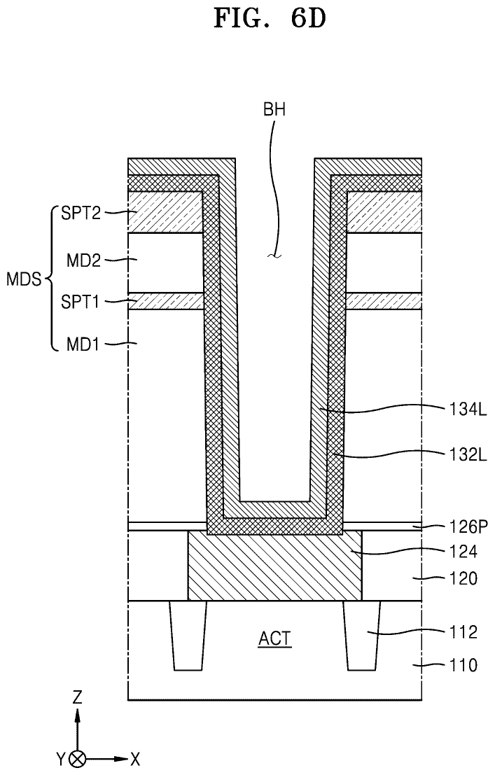

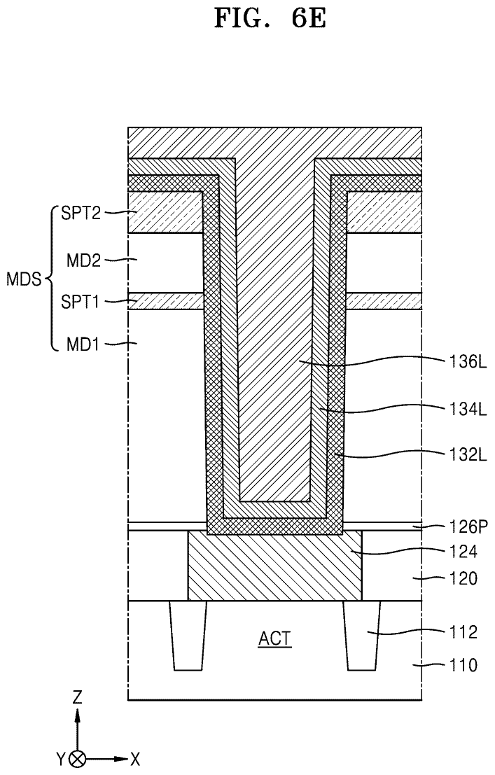

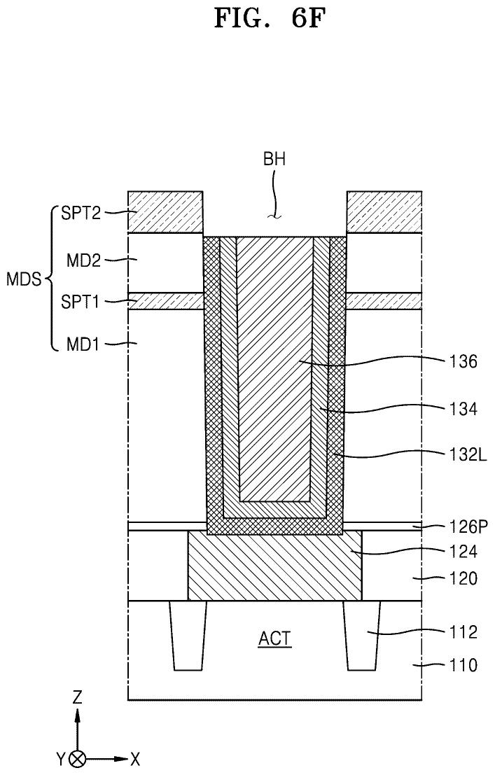

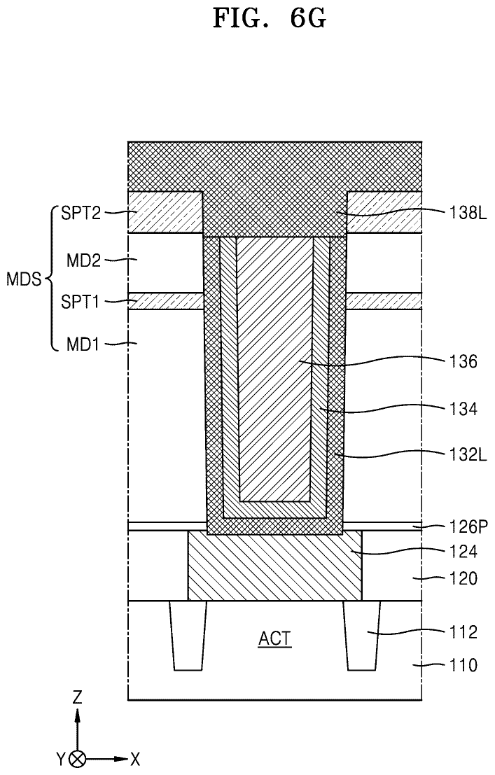

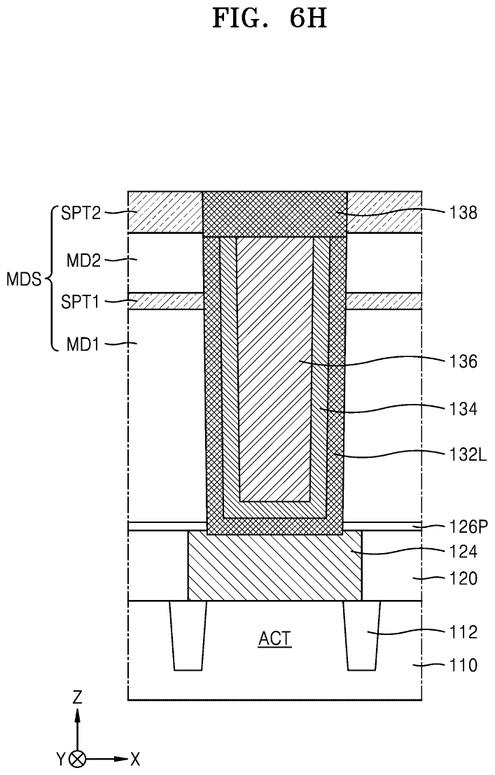

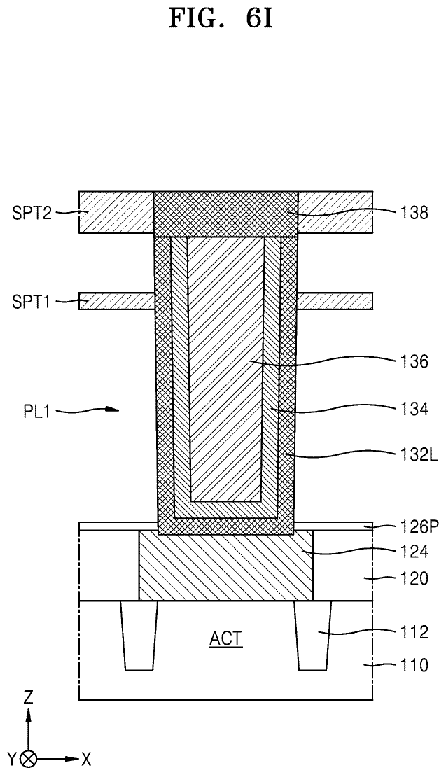

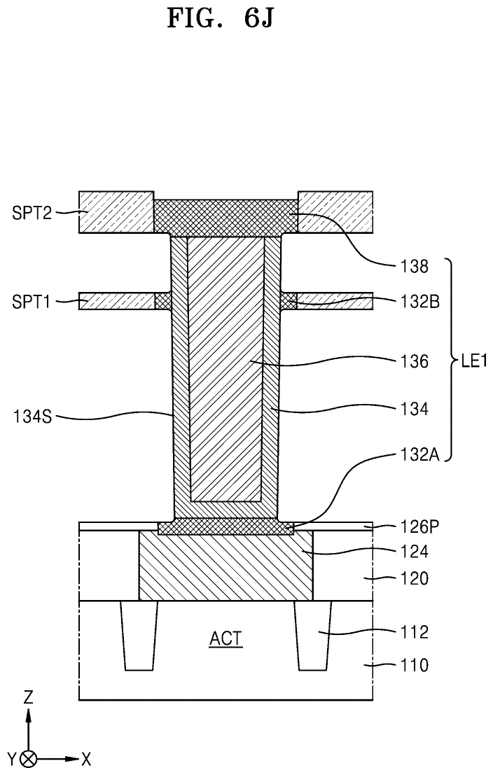

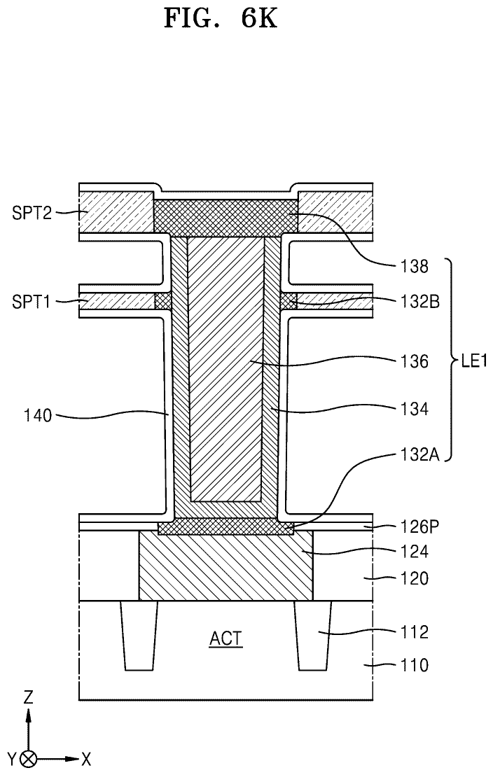

For example, the first metal oxide included in the outer template electrode portion 134 may include a material having an excellent etching resistance to a predetermined etching atmosphere, and the second metal oxide included in the main electrode portion 136 may include a low-resistance material including a relatively high electrical conductivity. More specifically, the first metal oxide included in the outer template electrode portion 134 may include a material (e.g., tin oxide) having a relatively high etching resistance to an etching atmosphere for removing a first mold film MD1 and a second mold film MD2, which are described below with reference to FIG. 6I during the manufacturing of the IC device 100. Due to the above-described configuration, even when the outer template electrode portion 134 is exposed after the first mold film MD1 and the second mold film MD2 are removed, the outer template electrode portion 134 may maintain the rutile-phase crystal structure without being damaged. As a result, when the dielectric film 140 is formed on a surface of the outer template electrode portion 134, the rutile-phase crystal structure of the dielectric film 140 may be strengthened by the outer template electrode portion 134.

Also, the second metal oxide included in the main electrode portion 136 may include a low-resistance material having a relatively high electrical conductivity, for example, vanadium oxide, molybdenum oxide, niobium oxide, cobalt oxide, or a combination thereof. Due to the above-described configuration, resistance of the lower electrode structure LE1 may be lowered, and the lower electrode structure LE1 may ensure relatively high electrical conductivity and thermal stability. In addition, because the second metal oxide included in the main electrode portion 136 has a rutile-phase crystal structure, the main electrode portion 136 may also serve to induce the dielectric film 140 to have a rutile-phase crystal structure together with the outer template electrode portion 134. As a result, the dielectric film 140 may maintain the rutile-phase crystal structure more effectively.

Furthermore, the lower electrode structure LE1 of the capacitor CP1 may include a bottom bridge electrode portion 132A covering the conductive region 124 between the outer template electrode portion 134 and the conductive region 124. Accordingly, in the process of manufacturing the IC device 100, during the formation of the outer template electrode portion 134 and the main electrode portion 136, which each include a metal oxide, there may be no concern that the conductive region 124 will be exposed to an oxidizing atmosphere for forming the metal oxide. Therefore, the conductive region 124 may be prevented from deteriorating due to oxidation during the formation of the outer template electrode portion 134 and the main electrode portion 136, and thus, interface resistance in the conductive region 124 may be effectively prevented from increasing.

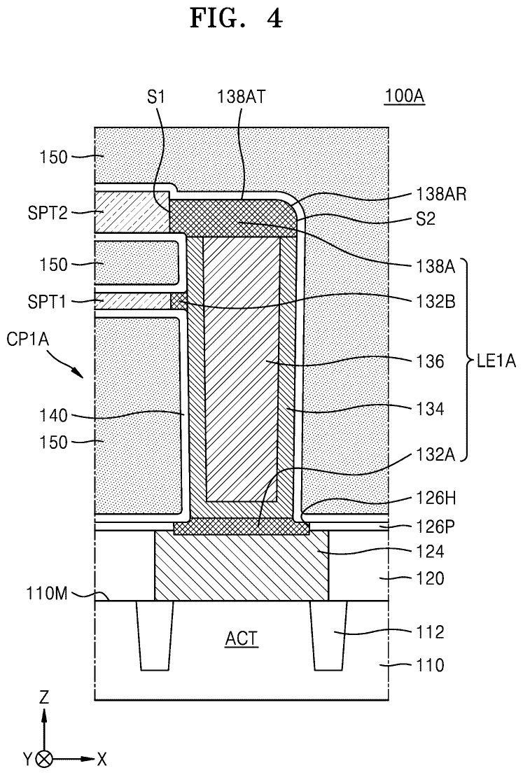

FIG. 4 is a cross-sectional view of some components of an IC device 100A according to embodiments. A cross-sectional configuration of the IC device 100A shown in FIG. 4 may correspond to a partial region of a cross-section taken along line X2-X2′ of FIG. 3. The IC device 100A may constitute a portion of the IC device 10 shown in FIG. 1. In FIG. 4, the same reference numerals are used to denote the same elements as in FIGS. 1 to 3, and repeated descriptions thereof are omitted here.

Referring to FIG. 4, the IC device 100A may substantially have the same configuration as the IC device 100 shown in FIG. 2. However, the IC device 100A may include a capacitor CP1A, which includes a lower electrode structure LE1A, an upper electrode 150, and a dielectric film 140 located between the lower electrode structure LE1A and the upper electrode 150. A first support film SPT1 and a second support film SPT2, which are configured to support the lower electrode structure LE1A, may be formed around the lower electrode structure LE1A. The lower electrode structure LE1A may constitute the lower electrode structure LE described with reference to FIG. 1.

The lower electrode structure LE1A may substantially have the same configuration as the lower electrode structure LE1 described with reference to FIG. 2. However, in the IC device 100A, the first support film SPT1 and the second support film SPT2 may contact the lower electrode structure LE1A only on one side of the lower electrode structure LE1A in a first lateral direction (X direction).

The lower electrode structure LE1A may include a capping electrode portion 138A in contact with the second support film SPT2. The capping electrode portion 138A may substantially have the same configuration as the capping electrode portion 138 described with reference to FIG. 2. However, a first sidewall S1, which is one of both sidewalls of the capping electrode portion 138A in the first lateral direction (X direction), may be in contact with the second support film SPT2, and a second sidewall S2, which another one of the both sidewalls, may be in contact with the dielectric film 140. A round corner 138AR may be provided between an uppermost surface 138AT of the capping electrode portion 138A and the second sidewall S2. In the first lateral direction (X direction), both sides of the capping electrode portion 138A may have an asymmetrical shape about a central axis of the lower electrode structure LE1A in the vertical direction (Z direction).

In the IC device 100A described with reference to FIG. 4, similarly to the IC device 100 described with reference to FIGS. 2 and 3, the dielectric film 140 may effectively maintain a rutile-phase crystal structure. Thus, the dielectric film 140 may provide a relatively high dielectric constant, leakage current between the lower electrode structure LE1A and the dielectric film 140 may be reduced or eliminated, and capacitance of the capacitor CP1A may increase. Furthermore, the conductive region 124 may be prevented from deteriorating due to oxidation during the manufacturing of the IC device 100A, and thus, interface resistance in the conductive region 124 may be effectively prevented from increasing, and reliability of the IC device 100A may improve.

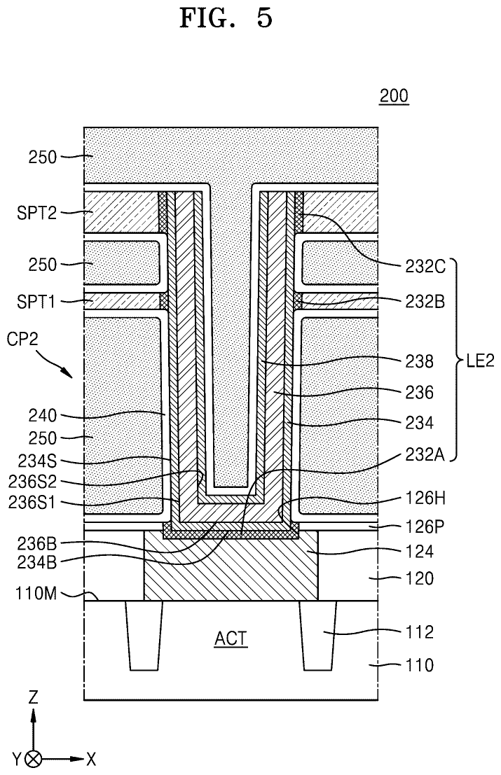

FIG. 5 is a cross-sectional view of some components of an IC device 200 according to still embodiments. A cross-sectional configuration of the IC device 200 shown in FIG. 5 may correspond to a partial region of the cross-section taken along line X1-X1′ of FIG. 3. The IC device 200 may constitute a portion of the IC device 10 shown in FIG. 1. In FIG. 5, the same reference numerals are used to denote the same elements as in FIGS. 1 to 3, and repeated descriptions thereof are omitted here.

Referring to FIG. 5, the IC device 200 may substantially have the same configuration as the IC device 100 shown in FIG. 2. However, the IC device 200 may include a capacitor CP2, which includes a lower electrode structure LE2, an upper electrode 250, and a dielectric film 240 located between the lower electrode structure LE2 and the upper electrode 250. The lower electrode structure LE2 may constitute the lower electrode structure LE described with reference to FIG. 1.

The lower electrode structure LE2 may extend lengthwise in a vertical direction (Z direction) from a top surface of a conductive region 124 through the opening 126H of the insulating pattern 126P. The dielectric film 240 and the upper electrode 250 may be formed on the lower electrode structure LE2.

The lower electrode structure LE2 may include a bottom bridge electrode portion 232A, an outer template electrode portion 234, a main electrode portion 236, and an inner template electrode portion 238, which are sequentially formed on the conductive region 124. In addition, the lower electrode structure LE2 may further include a first side bridge electrode portion 232B and a second side bridge electrode portion 232C. The first side bridge electrode potion 232B may protrude from the outer template electrode portion 234 toward the first support film SPT1 and be in contact with the first support film SPT1. The second side bridge electrode portion 232C may protrude from the outer template electrode portion 234 toward the second support film SPT2 and be in contact with the second support film SPT2.

The bottom bridge electrode portion 232A and the outer template electrode portion 234 of the lower electrode structure LE2 may respectively and substantially have the same configurations as the bottom bridge electrode portion 132A and the outer template electrode portion 134, which have been described with reference to FIG. 2. The outer template electrode portion 234 may have a bottom surface 234B in contact with a top surface of the bottom bridge electrode portion 232A and an outer sidewall 234S in contact with the dielectric film 240.

The main electrode portion 236 of the lower electrode structure LE2 may have an outer sidewall 236S1 in contact with the outer template electrode portion 234 and an inner sidewall 236S2 defining an inner space of the main electrode portion 236. The main electrode portion 236 may have a cylindrical shape having a cup-shaped cross-sectional structure. The dielectric film 240 and the upper electrode 250 may respectively and substantially have the same configurations as the dielectric film 140 and the upper electrode 150, which have been described with reference to FIG. 2. However, each of the dielectric film 240 and the upper electrode 250 may include a portion located in the inner space defined by the inner sidewall 236S2 of the main electrode portion 236. A constituent material of the main electrode portion 236 may be the same as that of the main electrode portion 136, which has been described with reference to FIG. 2. In the lower electrode structure LE2, the outer template electrode portion 234 may include a first metal oxide having a rutile-phase crystal structure. The main electrode portion 236 may include a second metal oxide, which includes a different material from the first metal oxide and has a rutile-phase crystal structure.

The inner template electrode portion 238 of the lower electrode structure LE2 may have a first surface in contact with the inner sidewall 236S2 of the main electrode portion 236 and a second surface in contact with the dielectric film 240 in the inner space defined by the inner sidewall 236S2 of the main electrode portion 236. A constituent material of each of the outer template electrode portion 234 and the inner template electrode portion 238 of the lower electrode structure LE2 may be the same as that of the outer template electrode portion 134, which has been described with reference to FIG. 2. The inner template electrode portion 238 of the lower electrode structure LE2 may include a third metal oxide including a different material from the second metal oxide included in the main electrode portion 236. In embodiments, in the lower electrode structure LE2, the first metal oxide included in the outer template electrode portion 234 may include the same material as the third metal oxide included in the inner template electrode portion 238.

Each of a first side bridge electrode portion 232B and a second side bridge electrode portion 232C of the lower electrode structure LE2 may have a surface in contact with an outer sidewall 234S of the outer template electrode portion 234. The first side bridge electrode portion 232B and the second side bridge electrode portion 232C may be spaced apart from each other in the vertical direction (Z direction). In the vertical direction (Z direction), a thickness of the second side bridge electrode portion 232C may be greater than a thickness of the first side bridge electrode portion 232B. A constituent material of each of the first side bridge electrode portion 232B and the second side bridge electrode portion 232C may be the same as that of the side bridge electrode portion 132B, which has been described with reference to FIG. 2.

In the IC device 200 described with reference to FIG. 5, the outer template electrode portion 234 and the inner template electrode portion 238 may act as crystallization-inducing layers configured to induce the dielectric film 240 to have a rutile-phase crystal structure. Due to the outer template electrode portion 234 and the inner template electrode portion 238, a material included in the dielectric film 240 may easily maintain the rutile-phase crystal structure. Thus, the dielectric film 240 may provide a relatively high dielectric constant, leakage current between the lower electrode structure LE2 and the dielectric film 240 may be reduced or eliminated, and capacitance of the capacitor CP2 may increase.

In the lower electrode structure LE2 of the capacitor CP2, the first and third metal oxides respectively included in the outer template electrode portion 234 and the inner template electrode portion 238 may each include a material having an excellent etching resistance to a predetermined etching atmosphere, and the second metal oxide included in the main electrode portion 236 may include a low-resistance material having a relatively high electrical conductivity. As a result, when the dielectric film 240 is formed on the outer template electrode portion 234 and the inner template electrode portion 238, the rutile-phase crystal structure of the dielectric film 240 may be strengthened by the outer template electrode portion 234 and the inner template electrode portion 238, resistance of the lower electrode structure LE2 may be lowered, and the lower electrode structure LE2 may ensure relatively high electrical conductivity and thermal stability. In addition, because the second metal oxide included in the main electrode portion 236 has a rutile-phase crystal structure, the main electrode portion 236 may also serve to induce the dielectric film 240 to have a rutile-phase crystal structure together with the outer template electrode portion 234 and the inner template electrode portion 238. Thus, the dielectric film 240 may maintain the rutile-phase crystal structure more effectively.

In addition, the lower electrode structure LE2 of the capacitor CP2 may include a bottom bridge electrode portion 232A covering the conductive region 124 between the outer template electrode portion 234 and the conductive region 124. Accordingly, in the process of manufacturing the IC device 200, during the formation of the outer template electrode portion 234, the main electrode portion 236, and the inner template electrode portion 238, which each include a metal oxide, there may be no concern that the conductive region 124 will be exposed to an oxidizing atmosphere for forming the metal oxide. Therefore, the conductive region 124 may be prevented from deteriorating due to oxidation during the formation of the outer template electrode portion 234, the main electrode portion 236, and the inner template electrode portion 238, and thus, interface resistance in the conductive region 124 may be effectively prevented from increasing.

Next, methods of manufacturing IC devices, according to embodiments, are described in detail with reference to specific examples.

FIGS. 6A to 6K are cross-sectional views of a process sequence of a method of manufacturing an IC device, according to embodiments. An example of a method of manufacturing the IC device 100 shown in FIG. 2 is described with reference to FIGS. 6A to 6K. In FIGS. 6A to 6K, the same reference numerals are used to denote the same elements as in FIGS. 1 to 3, and repeated descriptions thereof are omitted here.

Referring to FIG. 6A, a lower structure 120 and a conductive region 124 may be formed on a substrate 110 in which an active region is defined by a device isolation region 112. The conductive region 124 may pass through the lower structure 120 and be connected to the active region ACT. Thereafter, an insulating layer 126 may be formed to cover the lower structure 120 and the conductive region 124. The insulating layer 126 may be used as an etch stop layer in a subsequent process. The insulating layer 126 may include an insulating material having an etch selectivity with respect to the lower structure 120. In embodiments, the insulating layer 126 may include silicon nitride, silicon oxynitride, or a combination thereof.

A mold structure MDS may be formed on the insulating layer 126. To form the mold structure MDS, a first mold film MD1, a first support film SPT1, a second mold film MD2, and a second support film SPT2 may be sequentially formed on the insulating layer 126. Each of the first mold film MD1 and the second mold film MD2 may include an insulating material having an etch selectivity with respect to the insulating layer 126. In embodiments, each of the first mold film MD1 and the second mold film MD2 may include an oxide film. The first support film SPT1 and the second support film SPT2 may respectively include materials having etch selectivities with respect to the first mold film MD1 and the second mold film MD2. The first support film SPT1 and the second support film SPT2 may include a material having a relatively low etch rate with respect to an etching atmosphere (e.g., an etchant including ammonium fluoride (NH₄F), hydrofluoric acid (HF), and water), which is used to remove the first mold film MD1 and the second mold film MD2 in a subsequent process.

Referring to FIG. 6B, in the resultant structure of FIG. 6A, a mask pattern MP may be formed on the mold structure MDS. Then, the mold structure MDS may be anisotropically etched by using the mask pattern MP as an etch mask and by using the insulating layer 126 as an etch stop layer, and thus, a vertical hole BH may be formed in the mold structure MDS. The mask pattern MP may include a nitride film, an oxide film, a polysilicon film, a photoresist film, or a combination thereof. Thereafter, the insulating layer 126 may be anisotropically etched through the vertical hole BH by using the mask pattern MP as an etch mask to form an insulating pattern 126P having an opening 126H exposing the conductive region 124. During the formation of the opening 126H by using the anisotropic etching process, an upper portion of the conductive region 124 may be etched by over-etching, and thus, a recessed surface may be formed in a top surface of the conductive region 124.

Referring to FIG. 6C, the mask pattern MP may be removed from the resultant structure of FIG. 6B, and then a preliminary bridge electrode layer 132L may be formed to conformally cover a surface of the conductive region 124, a surface of the insulating pattern 126P, and a surface of the mold structure MDS inside and outside the vertical hole BH. After the preliminary bridge electrode layer 132L is formed, a portion of the vertical hole BH may be left empty on the preliminary bridge electrode layer 132L. A constituent material of the preliminary bridge electrode layer 132L may be the same as that of the bottom bridge electrode portion 132A, which has been described with reference to FIG. 2. The preliminary bridge electrode layer 132L may be formed by using a chemical vapor deposition (CVD) process, a metal organic CVD (MOCVD) process, or an atomic layer deposition (ALD) process.

Referring to FIG. 6D, a template electrode layer 134L covering the preliminary bridge electrode layer 132L may be formed inside the vertical hole BH. The template electrode layer 134L may conformally cover the preliminary bridge electrode layer 132L in the remaining space of the vertical hole BH defined by the preliminary bridge electrode layer 132L. The template electrode layer 134L may include a first metal oxide having a rutile-phase crystal structure. A detailed composition of a constituent material of the template electrode layer 134L may be the same as that of a constituent material of the outer template electrode portion 134, which has been described with reference to FIG. 2.

In embodiments, the template electrode layer 134L may include tin oxide having a rutile-phase crystal structure. The template electrode layer 134L may be formed by using an ALD process. In an example of the ALD process of forming the template electrode layer 134L, an ALD cycle described below may be repeated at least once.

During the ALD cycle, a Sn precursor may be supplied onto the substrate in the resultant structure of FIG. 6C while maintaining a process temperature at a temperature of about 100 °C to about 600 °C, for example, at a temperature of about 300 °C to about 400 °C. The Sn precursor may include R₂Sn(NR′R″)2 (here, R, R′, and R″ are each hydrogen (H) or a C1-C10 alkyl group), a Sn halide, or derivatives thereof, without being limited thereto. In this case, a process pressure may be maintained at a pressure of about 10 Pa to atmospheric pressure. In embodiments, to form the template electrode layer 134L, a supply gas including only a Sn precursor may be supplied onto the substrate 110. In embodiments, to form the template electrode layer 134L, a Sn precursor and a supply gas selectively including a dopant element, a compound including a dopant element, or a multi-component source including a reactive gas may be supplied onto the substrate 110. A period of time for which the supply gas is supplied onto the substrate 110 once may be maintained for about 0.1 seconds to about 100 seconds. The Sn precursor and the reactive gas may be simultaneously or sequentially supplied onto the substrate. By supplying the supply gas onto the substrate 110, a chemisorbed layer and a physisorbed layer of the Sn precursor may be formed on a surface of the preliminary bridge electrode layer 132L.

Afterwards, a first purge gas may be supplied onto the substrate 110 to remove unnecessary byproducts on the substrate 110. In this case, the physisorbed layer of the Sn precursor remaining on the substrate 110 may also be removed. For example, inert gases (e.g., argon (Ar), helium (He), and neon (Ne)), or N₂ gas may be used as the first purge gas.

Thereafter, an oxidative gas may be supplied onto the substrate 110, and thus, a monatomic thin oxide film may be formed from the chemisorbed layer of the Sn precursor. The oxidative gas may be selected from O₂, O₃, H₂O, NO₂, NO, N₂O, CO, CO₂, H 2O₂, HCOOH, CH₃COOH, (CH₃CO)₂O, alcohol, peroxide, sulfur oxide, plasma O₂, remote plasma O₂, plasma N₂O, plasma H₂O, and a combination thereof.

Afterwards, a second purge gas may be supplied onto the substrate 110 to remove unnecessary byproducts on the substrate 110. In this case, residue of the oxidative gas remaining on the substrate 110 may be removed. For example, inert gases (e.g., Ar, He, and Ne), or N2 gas may be used as the second purge gas.

Thereafter, it may be determined whether the template electrode layer 134L having a desired thickness has been obtained on the preliminary bridge electrode layer 132L, and the ALD cycle described above may be repeated at least once until the template electrode layer 134L having a target thickness is obtained.

Because the conductive region 124 is covered by the preliminary bridge electrode layer 132L during the formation of the template electrode layer 134L, even when an oxidative gas is supplied onto the substrate 110 to form the template electrode layer 134L, the conductive region 124 may be protected by the preliminary bridge electrode layer 132L and may not be exposed to the oxidative gas. Thus, the conductive region 124 may be prevented from deteriorating due to the oxidative gas or interface resistance in the conductive region 124 may be prevented from increasing.

Referring to FIG. 6E, in the resultant structure of FIG. 6D, a main electrode layer 136L covering the template electrode layer 134L may be formed inside the vertical hole BH. The main electrode layer 136L may be formed to fill the remaining space of the vertical hole BH on the template electrode layer 134L. The main electrode layer 136L may include a second metal oxide, which includes a different material from the first metal oxide included in the template electrode layer 134L and has a rutile-phase crystal structure.

The main electrode layer 136L may be formed by using an ALD process. The ALD process of forming the main electrode layer 136L may substantially be similar to the ALD process of forming the template electrode layer 134L, which has been described with reference to FIG. 6D. However, to form the main electrode layer 136L, a metal precursor including a different metal from a metal used to form the template electrode layer 134L may be used. In embodiments, to form the main electrode layer 136L, a vanadium (V) precursor, a molybdenum (Mo) precursor, a niobium (Nb) precursor, or a cobalt (Co) precursor may be used as the metal precursor.

The V precursor may include vanadium tetrachloride (VCl₄), vanadium pentachloride (VCl₅), vanadium pentafluoride (VF₅), tetrakis dimethylaminovanadium (TDMAV, V(N(CH₃)₂)₄), tetrakis diethylaminovanadium (TDEAV, V(NEt₂)₄), tetrakis(methylethylamido) vanadium (TMEAV, V(NMeEt)₄), bis(cyclopentadienyl) vanadium (Cp₂V), bis(cyclopentadienyl) dichlorovanadium (Cp₂VCl₂), or derivatives thereof, without being limited thereto.

The Mo precursor may include (CpR)₂Mo(NR′) (R and R′ are each H or a C1-C10 alkyl group), or a Mo halide, without being limited thereto.

The Nb precursor may include niobium pentachloride (NbCl₅), niobiumpentafluoride (NbF₅), pentakis dimethylaminoniobium (PDMAN, Nb(N(CH₃)₂)₅), pentakis diethylaminoniobium (PDEAN, Nb(NEt₂)₅), pentakis(methylethylamido) niobium (PMEAN, Nb(NMeEt)₅), tert-butyliminotris(dimethylamino) niobium (TBTDMN, tBuNNb(NMe₂)₃), tert-butyliminotris(diethylamino) niobium (TBTDEN, tBuNNb(NEt₂)₃), tert-butyliminotris(methylethylamino) niobium (TBTMEN, tBuNNb(NMeEt)₃), ethylimido-tris(dimethylamido) niobium ((EtN)Nb(NMe₂)₃), ethylimido-tris(diethylamido) niobium ((EtN)Nb(NEt₂)₃), ethylimido-tris(ethylmethylamido) niobium ((EtN)Nb[N(Et)Me]₃), or derivatives thereof, without being limited thereto.

The Co precursor may be selected from di-cobalt octacarbonyl, cobalt nitrosyl complexes, β-diketonates of cobalt (II) and cobalt (III), or derivatives thereof, without being limited thereto.

Referring to FIG. 6F, in the resultant structure of FIG. 6E, the main electrode layer 136L, the template electrode layer 134L, and the preliminary bridge electrode layer 132L may be etched to expose a top surface and a sidewall of the second support film SPT2 included in the mold structure MDS. As a result, an outer template electrode portion 134 and a main electrode portion 136 may be formed on the preliminary bridge electrode layer 132L inside the vertical hole BH. The outer template electrode portion 134 may include the remaining portion of the template electrode layer 134L, and the main electrode portion 136 may include the remaining portion of the main electrode layer 136L. The main electrode portion 136 may cover the outer template electrode portion 134 inside the vertical hole BH. A portion of the vertical hole BH may be left empty on a top surface of each of the preliminary bridge electrode layer 132L, the outer template electrode portion 134, and the main electrode portion 136.

Referring to FIG. 6G, in the resultant structure of FIG. 6F, a capping electrode layer 138L filling the vertical hole BH may be formed on the top surface of each of the preliminary bridge electrode layer 132L, the outer template electrode portion 134, and the main electrode portion 136. The capping electrode layer 138L may be formed to fill the vertical hole BH and cover a top surface of the second support film SPT2. A constituent material of the capping electrode layer 138L may be the same as that of the main electrode portion 136, which has been described with reference to FIG. 2. The capping electrode layer 138L may be formed by using a CVD process, an MOCVD process, or an ALD process.

Referring to FIG. 6H, in the resultant structure of FIG. 6G, the capping electrode layer 138L may be etched back to expose the top surface of the second support film SPT2. As a result, a capping electrode portion 138, which includes the remaining portion of the capping electrode layer 138L, may be obtained. A top surface of the capping electrode portion 138 may be coplanar with the top surface of the second support film SPT2.

Referring to FIG. 6I, in the resultant structure of FIG. 6H, the first mold film MD1 and the second mold film MD2 may be selectively removed from the first mold film MD1, the first support film SPT1, the second mold film MD2, and the second support film SPT2, which are included in the mold structure MDS, and thus, a sidewall of the preliminary bridge electrode layer 132L and a top surface of the insulating pattern 126P may be exposed. The first mold film MD1 and the second mold film MD2 may be removed by using a wet etching process. For example, the first mold film MD1 and the second mold film MD2 may be removed by using an etchant including ammonium fluoride (NH₄F), hydrofluoric acid (HF), and water. In an example of the process of removing the first mold film MD1 and the second mold film MD2, initially, a plurality of upper holes (refer to UH in FIG. 3) may be formed in the second support film SPT2 by patterning the second support film SPT2, and the second mold film MD2 may be removed through the plurality of upper holes UH of the second support film SPT2. Thereafter, a plurality of lower holes may be formed at positions corresponding to the plurality of upper holes UH in the first support film SPT1, and the first mold film MD1 may be removed through the plurality of lower holes of the first support film SPT1. During the removal of the first mold film MD1 and the second mold film MD2, a preliminary lower electrode structure PL1, which includes the preliminary bridge electrode layer 132L, the outer template electrode portion 134, the main electrode portion 136, and the capping electrode portion 138, may be supported by the first support film SPT1 and the second support film SPT2.

Even when the outer template electrode portion 134 is exposed to an etching atmosphere for removing the first mold film MD1 and the second mold film MD2 during the removal of the first mold film MD1 and the second mold film MD2, because the outer template electrode portion 134 includes a material (e.g., tin oxide) having a relatively high etching resistance to the etching atmosphere, the outer template electrode portion 134, which is exposed after the first mold film MD1 and the second mold film MD2 are removed, may maintain the rutile-phase crystal structure without being damaged.

Referring to FIG. 6J, in the resultant structure of FIG. 6I, a portion of the preliminary bridge electrode layer 132L may be removed from the exposed sidewall of the preliminary bridge electrode layer 132L to expose an outer sidewall 134S of the outer template electrode portion 134. By removing the portion of the preliminary bridge electrode layer 132L, a bottom bridge electrode portion 132A and a side bridge electrode portion 132B may be formed. The bottom bridge electrode portion 132A may include the remaining portion of the preliminary bridge electrode layer 132L, and the side bridge electrode portion 132B may include the remaining other portion of the preliminary bridge electrode layer 132L.

To remove the portion of the preliminary bridge electrode layer 132L, a wet etching process may be performed by using a difference in etch selectivity between a material included in the outer template electrode portion 134 and a material included in the preliminary bridge electrode layer 132L. For example, when the preliminary bridge electrode layer 132L includes titanium nitride (TiN), partial regions may be selectively etched from the exposed portion of the preliminary bridge electrode layer 132L by means of a wet etching process using an etchant including sulfuric acid (H₂SO₄) and hydrogen peroxide (H₂O₂). However, the etching process of removing the portion of the preliminary bridge electrode layer 132L is not limited thereto.

When the preliminary bridge electrode layer 132L and the capping electrode portion 138 include the same material, a portion of the capping electrode portion 138 may be removed from an exposed top surface thereof during the selective removal of the portion of the preliminary bridge electrode layer 132L, and thus, a thickness of the capping electrode portion 138 may be reduced as shown in FIG. 6J. After the thickness of the capping electrode portion 138 is reduced, a vertical level of an uppermost surface of the capping electrode portion 138 may be closer to the substrate 110 than a vertical level of an uppermost surface of the second support film SPT2. In the resultant structure obtained after the portion of the preliminary bridge electrode layer 132L is removed, the bottom bridge electrode portion 132A, the side bridge electrode portion 132B, the outer template electrode portion 134, the main electrode portion 136, and the capping electrode portion 138 may constitute a lower electrode structure LE1.

Referring to FIG. 6K, a dielectric film 140 covering an exposed surface of the lower electrode structure LE1 may be formed in the resultant structure of FIG. 6J. In embodiments, the dielectric film 140 may be formed by using an ALD process.

In the ALD process of forming the dielectric film 140, an ALD cycle described below may be repeated at least once. Initially, a Ti precursor may be supplied onto the substrate 110 on which the lower electrode structure LE1 is exposed inside a reaction space, and thus, a Ti precursor layer may be formed on a surface of each of the lower electrode structure LE1, the insulating pattern 126P, the first support film SPT1, and the second support film SPT2. The Ti precursor may include titanium tetrachloride (TiCl₄), titanium tetrafluoride (TiF₄), titanium tetrakis(isopropoxide) (Ti(O—iPr)₄), cyclopentadienyl titanium, titanium bis(isopropoxide)bis(2,2,6,6-tetramethyl-3,5-heptanedionate) (Ti(O—iPr)₂(thd)₂), tetrakis dimethylaminotitanium (TDMAT, Ti(NMe₂)₄), tetrakis(diethylamino) titanium (TEMAT, (Et₂N)₄Ti), trimethoxy(pentamethylcyclopentadienyl) titanium ((Cp*)Ti(OMe)₃), or derivatives thereof, without being limited thereto. The Ti precursor may be supplied onto the substrate 110 in a vaporized state. While the Ti precursor is being supplied onto the substrate 110, the inside of a reaction space into which the substrate 110 is loaded may be maintained at a temperature selected in a range of about 100 °C to about 600 °C. By supplying the Ti precursor onto the substrate 110 in a vaporized state, a chemisorbed layer and a physisorbed layer of the Ti precursor may be formed on a surface of each of the lower electrode structure LE1, the insulating pattern 126P, the first support film SPT1, and the second support film SPT2. Then, a purge gas may be supplied onto the substrate 110 in the reaction space to remove unnecessary byproducts on the substrate 110. In this case, the physisorbed layer of the Ti precursor remaining on the substrate 110 may also be removed. For example, inert gases (e.g., Ar, He, and Ne), or N₂ gas may be used as the purge gas. Afterwards, an oxidative reactive gas may be supplied onto the substrate 110, and thus, a metal oxide film may be formed from the chemisorbed layer of the metal precursor. The oxidative reactive gas may include O₂, O₃, plasma O₂, H₂O, NO₂, NO, N₂O, CO₂, H₂O₂, HCOOH, CH₃COOH, (CH₃CO)₂O, or a combination thereof. Thereafter, a purge gas may be supplied onto the substrate 110 to remove unnecessary products on the substrate 110. The ALD cycle described above may be repeated at least once until a TiO₂ film having a desired thickness is obtained. Portions of the TiO₂ film, which are in contact with at least the outer template electrode portion 134, may have a rutile-phase crystal structure. To form the dielectric film 140, at least one high-k dielectric film may be further formed on the TiO₂ film as needed.

Subsequently, an upper electrode 150 covering the dielectric film 140 may be formed on the resultant structure of FIG. 6K, and thus, the IC device 100 including the capacitor CP1 shown in FIG. 2 may be manufactured. The upper electrode 150 may be formed by using a CVD process, an MOCVD process, a physical vapor deposition (PVD) process, or an ALD process.

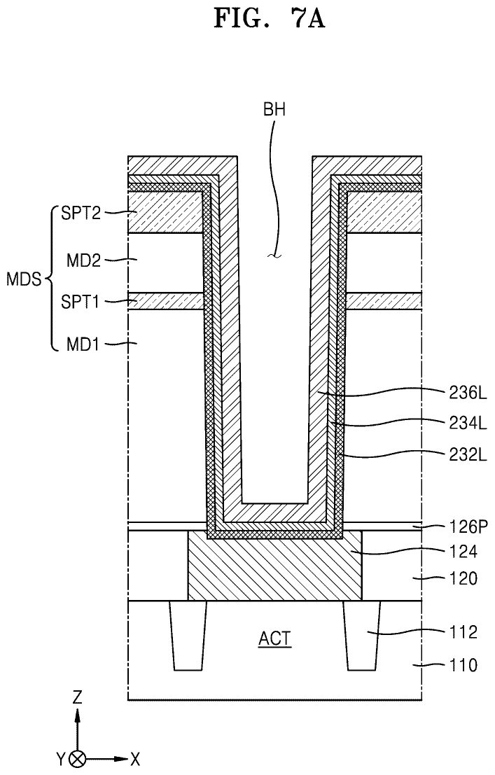

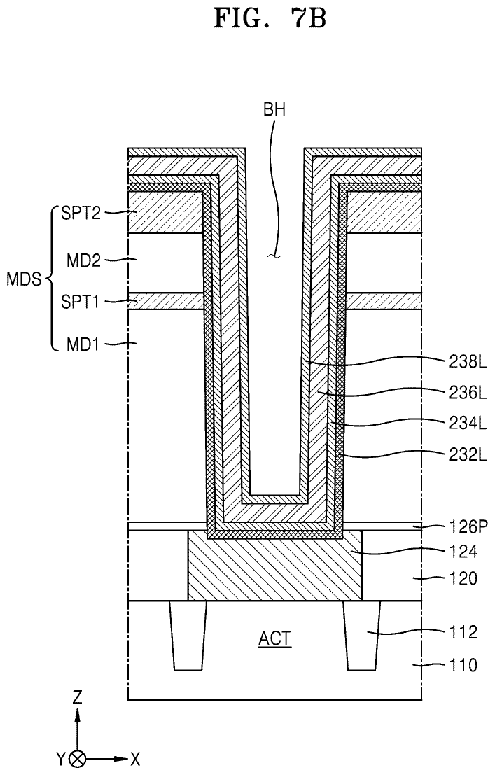

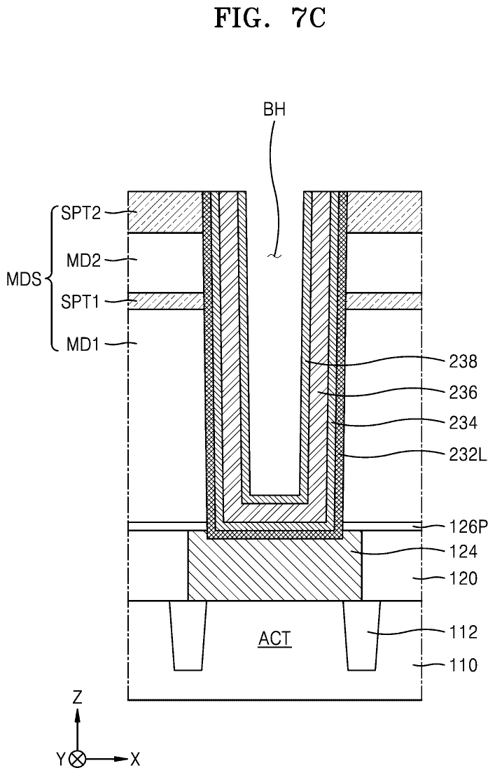

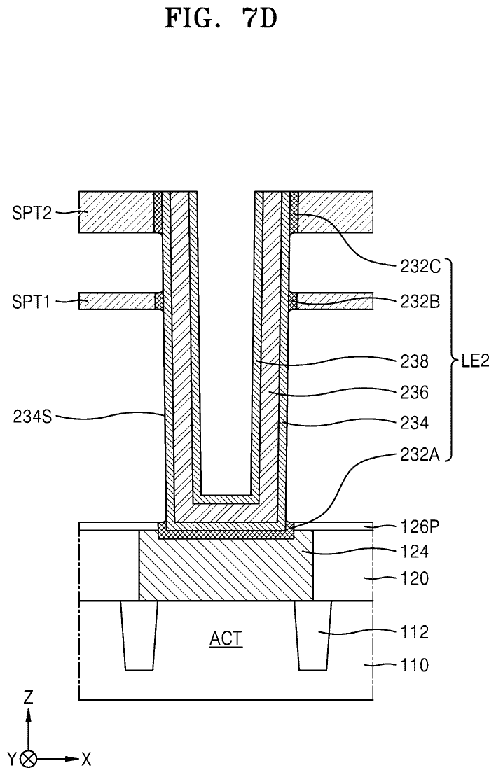

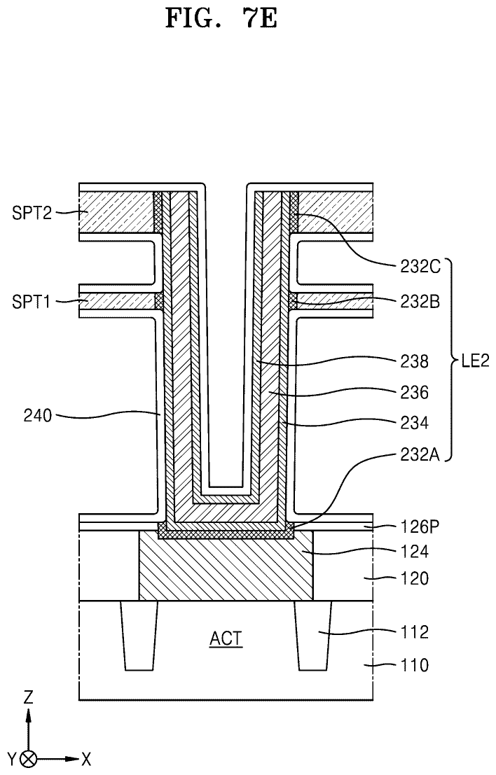

FIGS. 7A to 7E are cross-sectional views of a process sequence of a method of manufacturing an IC device, according to embodiments. An example of a method of manufacturing the IC device 200 shown in FIG. 5 is described with reference to FIGS. 7A to 7E. In FIGS. 7A to 7E, the same reference numerals are used to denote the same elements as in FIGS. 1 to 3, and repeated descriptions thereof are omitted here.

Referring to FIG. 7A, after the processes described with reference to FIGS. 6A and 6B are performed, a mask pattern MP may be removed from the resultant structure of FIG. 6B, and a preliminary bridge electrode layer 232L, a first template electrode layer 234L, and a main electrode layer 236L may be sequentially formed on a surface of a conductive region 124, a surface of an insulating pattern 126P, and a surface of a mold structure MDS inside or outside a vertical hole BH. Processes of forming the preliminary bridge electrode layer 232L, the first template electrode layer 234L, and the main electrode layer 236L may be respectively and substantially similar to the processes of forming the preliminary bridge electrode layer 132L, the template electrode layer 134L, and the main electrode layer 136L, which have been described with reference to FIGS. 6C, 6D, and 6E. However, the main electrode layer 236L may be formed to conformally cover the first template electrode layer 234L to a substantially constant thickness. After the main electrode layer 236L is formed, a portion of the vertical hole BH may be left empty on the main electrode layer 236L.

A constituent material of the preliminary bridge electrode layer 232L may be the same as those of the bottom bridge electrode portion 232A, the first side bridge electrode portion 232B, and the second side bridge electrode portion 232C, which have been described with reference to FIG. 5. For example, the preliminary bridge electrode layer 232L may include TiN. A constituent material of the first template electrode layer 234L may be the same as that of the outer template electrode portion 134, which has been described with reference to FIG. 2. A constituent material of the main electrode layer 236L may be the same as that of the main electrode portion 136, which has been described with reference to FIG. 2.

Referring to FIG. 7B, a second template electrode layer 238L conformally covering an exposed surface of the main electrode layer 236L may be formed in the resultant structure of FIG. 7A. The process of forming the second template electrode layer 238L may substantially be similar to the process of forming the template electrode layer 134L, which has been described with reference to FIG. 6D. In embodiments, a constituent material of the second template electrode layer 238L may be the same as that of the first template electrode layer 234L.

Referring to FIG. 7C, the second template electrode layer 238L, the main electrode layer 236L, the first template electrode layer 234L, and the preliminary bridge electrode layer 232L may be etched back from the resultant structure of FIG. 7B to expose a top surface of the second support film SPT2 included in the mold structure MDS. As a result, an outer template electrode portion 234, a main electrode portion 236, and an inner template electrode portion 238 may be formed on the preliminary bridge electrode layer 232L. The outer template electrode portion 234 may include the remaining portion of the first template electrode layer 234L. The main electrode portion 236 may include the remaining portion of the main electrode layer 236L. The inner template electrode portion 238 may include the remaining portion of the second template electrode layer 238L. A portion of the vertical hole BH may be left empty on the inner template electrode portion 238.

Referring to FIG. 7D, in a similar manner to that described with reference to FIG. 6I, the first mold film MD1 and the second mold film MD2 may be removed from the resultant structure of FIG. 7C, and a sidewall of the preliminary bridge electrode layer 232L may be exposed.

Thereafter, in a similar manner to that described with reference to FIG. 6J, an exposed portion of the preliminary bridge electrode layer 232L may be removed to expose an outer sidewall 234S of the outer template electrode portion 234 and form a bottom bridge electrode portion 232A, a first side bridge electrode portion 232B, and a second side bridge electrode portion 232C, which include the remaining portion of the preliminary bridge electrode layer 232L. The bottom bridge electrode portion 232A, the first side bridge electrode portion 232B, the second side bridge electrode portion 232C, the outer template electrode portion 234, the main electrode portion 236, and the inner template electrode portion 238 may constitute a lower electrode structure LE2.

Referring to FIG. 7E, in a similar manner to the process of forming the dielectric film 140, which has been described with reference to FIG. 6K, a dielectric film 240 covering an exposed surface of the lower electrode structure LE2 may be formed on the resultant structure of FIG. 7D.

Subsequently, an upper electrode 250 covering the dielectric film 240 may be formed on the resultant structure of FIG. 7E, and thus, the IC device 200 including the capacitor CP2, which is shown in FIG. 5, may be manufactured.

Although the methods of manufacturing the IC devices 100 and 200 shown in FIGS. 2 and 5 have been described with reference to FIGS. 6A to 6K and 7A to 7E, it will be understood that the IC device 100A shown in FIG. 4 or IC devices having variously changed structures may be manufactured by applying various modifications and changes to the IC devices 100, 100A, and 200 shown in FIGS. 2 to 5, based on the descriptions provided with reference to FIGS. 6A to 6K and 7A to 7E, within the scope of the inventive concept.

While the inventive concept has been particularly shown and described with reference to embodiments thereof, it will be understood that various changes in form and details may be made therein without departing from the spirit and scope of the following claims.

What is claimed is:

1. An integrated circuit device comprising:
a conductive region on a substrate; and
a capacitor located on the conductive region, the capacitor comprising a lower electrode structure, an upper electrode, and a dielectric film located between the lower electrode structure and the upper electrode,
wherein the lower electrode structure comprises:
an outer template electrode portion spaced apart from the conductive region in a substantially vertical direction, the outer template electrode portion being in contact with the dielectric film and comprising a first metal oxide having a rutile-phase crystal structure;
a main electrode portion having a first bottom surface and a first outer sidewall, wherein the first bottom surface and the first outer sidewall are in contact with the outer template electrode portion, the main electrode portion comprising a second metal oxide and being spaced apart from the dielectric film with the outer template electrode portion therebetween, wherein the second metal oxide comprises a different material from a material of the first metal oxide and has a rutile-phase crystal structure; and
a bottom bridge electrode portion located between the conductive region and the outer template electrode portion and spaced apart in the substantially vertical direction from the main electrode portion with the outer template electrode portion therebetween, the bottom bridge electrode portion comprising a conductive metal nitride.

2. The integrated circuit device of claim 1, wherein:
the outer template electrode portion has a second bottom surface facing the conductive region and has a second outer sidewall facing the upper electrode,
the second bottom surface of the outer template electrode portion is in contact with the bottom bridge electrode portion, and
the second outer sidewall of the outer template electrode portion is in contact with the dielectric film.

3. The integrated circuit device of claim 1, wherein:
the lower electrode structure further comprises a capping electrode portion covering an uppermost surface of each of the outer template electrode portion and the main electrode portion, and
the capping electrode portion and the bottom bridge electrode portion comprise a same material.

4. The integrated circuit device of claim 1, further comprising at least one support film configured to support the lower electrode structure around the lower electrode structure,
wherein:
the lower electrode structure further comprises at least one side bridge electrode portion extending from the outer template electrode portion toward the at least one support film, and
the at least one side bridge electrode portion and the bottom bridge electrode portion comprise a same material.

5. The integrated circuit device of claim 1, further comprising a first support film and a second support film, the first and second support films being configured to support the lower electrode structure around the lower electrode structure,
wherein:
the second support film is spaced apart in the substantially vertical direction from the substrate with the first support film therebetween, and
the lower electrode structure further comprises:
a capping electrode portion covering an uppermost surface of each of the outer template electrode portion and the main electrode portion; and
a side bridge electrode portion extending from the outer template electrode portion toward the first support film,
wherein the second support film is in contact with the outer template electrode portion.

6. The integrated circuit device of claim 5, wherein the capping electrode portion, the side bridge electrode portion, and the bottom bridge electrode portion comprise a same material.

7. The integrated circuit device of claim 5, wherein:
in the substantially vertical direction, a thickness of the second support film is greater than a thickness of the first support film, and,
in the substantially vertical direction, a thickness of the capping electrode portion is greater than a thickness of the side bridge electrode portion.

8. The integrated circuit device of claim 1, wherein the main electrode portion has a pillar shape with a filled interior.

9. The integrated circuit device of claim 1, wherein:
the main electrode portion has a cylindrical shape having a cup-shaped cross-sectional structure with an inner sidewall defining an inner space,
the lower electrode structure further comprises an inner template electrode portion having a first surface in contact with the inner sidewall of the main electrode portion and having a second surface in contact with the dielectric film in the inner space defined by the main electrode portion, and
the inner template electrode portion comprises a third metal oxide having a rutile-phase crystal structure, the third metal oxide comprising a different material from the second metal oxide included in the main electrode portion.

10. The integrated circuit device of claim 9, wherein the first metal oxide included in the outer template electrode portion comprises a same material as the third metal oxide included in the inner template electrode portion.

11. The integrated circuit device of claim 9, wherein:
each of the dielectric film and the upper electrode comprises a portion located in the inner space defined by the main electrode portion, and
the inner template electrode portion is in contact with the dielectric film in the inner space defined by the main electrode portion.

12. The integrated circuit device of claim 1, wherein the outer template electrode portion comprises a dopant-free tin oxide.

13. The integrated circuit device of claim 1, wherein the outer template electrode portion further comprises a dopant comprising at least one element selected from niobium (Nb), antimony (Sb), and tantalum (Ta).

14. The integrated circuit device of claim 1, wherein the main electrode portion comprises vanadium oxide, molybdenum oxide, niobium oxide, cobalt oxide, or a combination thereof.

15. The integrated circuit device of claim 1, wherein:
the main electrode portion further comprises a dopant comprising tin (Sn), and
a content of the dopant in the main electrode portion is in a range of 0.0 atomic percent (at %) to about 10 at %.

16. The integrated circuit device of claim 1, wherein the dielectric film comprises a TiO₂ film having a rutile-phase crystal structure, the TiO₂ film being in contact with the outer template electrode portion.

17. The integrated circuit device of claim 1, wherein the bottom bridge electrode portion comprises titanium nitride (TiN).

18. An integrated circuit device comprising:
a conductive region on a substrate;
a lower electrode structure located on the conductive region;
a support film configured to support the lower electrode structure around the lower electrode structure;
an upper electrode facing the lower electrode structure on the substrate; and
a dielectric film located between the lower electrode structure and the upper electrode,
wherein the lower electrode structure comprises:
an outer template electrode portion spaced apart from the conductive region in a substantially vertical direction, the outer template electrode portion being in contact with the dielectric film and comprising a first metal oxide having a rutile-phase crystal structure;
a main electrode portion having a first bottom surface and a first outer sidewall in contact with the outer template electrode portion, the main electrode portion comprising a second metal oxide and being spaced apart from the dielectric film with the outer template electrode portion therebetween, wherein the second metal oxide comprises a different material from a material of the first metal oxide and has a rutile-phase crystal structure;
a bottom bridge electrode portion located between the conductive region and the outer template electrode portion and spaced apart in the substantially vertical direction from the main electrode portion with the outer template electrode portion therebetween; and
a side bridge electrode portion located between the outer template electrode portion and the support film and spaced apart from the bottom bridge electrode portion,
wherein the bottom bridge electrode portion and the side bridge electrode portion comprise the same conductive metal nitride.

19. The integrated circuit device of claim 18, wherein:
the lower electrode structure further comprises a capping electrode portion covering an uppermost surface of each of the outer template electrode portion and the main electrode portion, the capping electrode portion being spaced apart from each of the bottom bridge electrode portion and the side bridge electrode portion, and
the bottom bridge electrode portion, the side bridge electrode portion, and the capping electrode portion comprise a same conductive metal nitride.

20. An integrated circuit device comprising:
a conductive region on a substrate;
a lower electrode structure located on the conductive region;
a support film configured to support the lower electrode structure around the lower electrode structure;
an upper electrode facing the lower electrode structure on the substrate; and
a dielectric film located between the lower electrode structure and the upper electrode,
wherein the lower electrode structure comprises:
an outer template electrode portion spaced apart from the conductive region in a substantially vertical direction, the outer template electrode portion being in contact with the dielectric film and comprising tin oxide having a rutile-phase crystal structure;
a main electrode portion having a first bottom surface and a first outer sidewall, wherein the first bottom surface and the first outer sidewall are in contact with the outer template electrode portion, the main electrode portion comprising vanadium oxide, molybdenum oxide, niobium oxide, cobalt oxide, or a combination thereof and having a rutile-phase crystal structure, and the main electrode portion being spaced apart from the dielectric film with the outer template electrode portion therebetween;
a bottom bridge electrode portion located between the conductive region and the outer template electrode portion and spaced apart in the substantially vertical direction from the main electrode portion with the outer template electrode portion therebetween; and
a side bridge electrode portion located between the outer template electrode portion and the support film and spaced apart from the bottom bridge electrode portion,
wherein each of the bottom bridge electrode portion and the side bridge electrode portion comprises titanium nitride (TiN), and
the dielectric film comprises a TiO₂ film having a rutile-phase crystal structure, the TiO₂ film being in contact with the outer template electrode portion.
